(19) United States
(12) Patent Application Publication
(10) Pub. No.: US 2019/0027453 A1
(43) Pub. Date: Jan. 24, 2019

(54) SEMICONDUCTOR DEVICES

(71) Applicant: SAMSUNG ELECTRONICS CO., LTD., SUWON-SI (KR)

(72) Inventors: YONG HO KIM, DAEGU (KR); BO IN NOH, SUWON-Si (KR); SOO JEOUNG PARK, HWASEONG-SI (KR); IN YOUNG LEE, YONGIN-SI (KR)

(21) Appl. No.: 15/869,977

(22) Filed: Jan. 12, 2018

(30) Foreign Application Priority Data
Jul. 24, 2017 (KR) 10-2017-0093566

(51) Int. Cl. H01L 23/00

(52) U.S. Cl. CPC H01L 24/13; H01L 2924/07025; H01L 2224/0401; H01L 2224/05124; H01L 2224/05566; H01L 2224/05573; H01L 2224/05671; H01L 2224/05647; H01L 2224/05666; H01L 2224/05684; H01L 2224/05624; H01L 2224/05655; H01L 2224/05672; H01L 2224/05644; H01L 2224/13026; H01L 2224/13018; H01L 2224/13082; H01L 2224/13155; H01L 2224/13147; H01L 2224/13164; H01L 2224/13169; H01L 2224/13144; H01L 2224/13139; H01L 2224/13111; H01L 2224/02251; H01L 2224/0226; H01L 2924/05042; H01L 2924/05442; H01L 24/05

(57) ABSTRACT

A semiconductor device includes a substrate, a protection layer on the substrate that includes a trench that penetrates therethrough, a lower bump that includes a first part that fills at least a portion of the trench and a second part on the protection layer; and an upper bump on the lower bump. The protection layer includes a first part that surrounds the trench and a second part that surrounds the first part. A first height from an upper surface of the substrate to an upper surface of the first part of the protection layer is greater than a second height from the upper surface of the substrate to an upper surface of the second part of the protection layer.

### CROSS-REFERENCE TO RELATED APPLICATION

This application claims priority under 35 U.S.C. § 119 from, and the benefit of, Korean Patent Application No. 10-2017-0093566, filed on Jul. 24, 2017 in the Korean Intellectual Property Office, the contents of which are herein incorporated by reference in their entirety.

### TECHNICAL FIELD

Exemplary embodiments of the present disclosure are directed to semiconductor devices.

### DISCUSSION OF RELATED ART

A light, thin, short and small semiconductor device, e.g., a semiconductor chip, can be connected to an external power source or another semiconductor device through small external terminals, configured to transmit electrical signals therebetween. The small external terminals can affect the reliability of a semiconductor package that includes a semiconductor device. In a conventional external terminal, the stiffness of Cu is greater than the solder, and thus cracks can occur in a BEOL layer. If the solder height of the Cu pillar bump is increased to prevent this phenomenon, the solder may collapse to the side of the Cu post during reflow.

### SUMMARY

According to exemplary embodiments of the inventive concepts, a semiconductor device includes a substrate, a protection layer on the substrate that includes a trench that penetrates therethrough, a lower bump that includes a first part that fills at least a portion of the trench and a second part on the protection layer, and an upper bump on the lower bump. The protection layer includes a first part that surrounds the trench and a second part that surrounds the first part. A first height from an upper surface of the substrate to an upper surface of the first part of the protection layer is greater than a second height from the upper surface of the substrate to an upper surface of the second part of the protection layer.

According to exemplary embodiments of the inventive concepts, a semiconductor device includes a substrate that includes a pad, a protection layer on the substrate that includes a trench that exposes the pad, a lower bump that includes a first part that fills at least a portion of the trench and a second part on the protection layer, and an upper bump on the lower bump. A height from a bottom surface of the trench to an uppermost surface of the protection layer is from 0.3 to 0.7 times a height from the bottom surface of the trench to an upper surface of the second part of the lower bump.

According to exemplary embodiments of the inventive concepts, a semiconductor device includes a substrate that includes a pad, a conductive pattern on the pad, a lower bump on the conductive pattern, a protection layer on the substrate that includes a first part that covers at least a portion of a sidewall of the lower bump and a second part that surrounds the first part, and an upper bump on the lower bump that includes a first part that protrudes into the lower bump and a second part on the first part. The first part of the protection layer protrudes above the second part of the protection layer.

### BRIEF DESCRIPTION OF THE DRAWINGS

FIG. 1 is a cross-sectional view of a semiconductor device according to exemplary embodiments.

FIG. 2 is an enlarged view of portion k of FIG. 1.

FIG. 3 is an enlarged view of portion j of FIG. 2.

FIGS. 4 to 6 are plan views of a semiconductor device according to exemplary embodiments.

FIG. 7 is a cross-sectional view of a semiconductor device according to exemplary embodiments.

FIG. 8 is a cross-sectional view of a semiconductor device according to exemplary embodiments.

FIG. 9 is an enlarged view of portion m of FIG. 8.

FIG. 10 is an enlarged view of portion n of FIG. 9.

FIG. 11 is a cross-sectional view of a semiconductor device according to exemplary embodiments.

FIG. 12 is a cross-sectional view of a semiconductor device according to exemplary embodiments.

FIG. 13 is a cross-sectional view of a semiconductor device according to exemplary embodiments.

FIG. 14 illustrates a semiconductor package that includes a semiconductor device according to exemplary embodiments.

FIGS. 15 to 18 illustrate a method of manufacturing a semiconductor device according to exemplary embodiments.

### DETAILED DESCRIPTION

Various exemplary embodiments will now be described more fully hereinafter with reference to the accompanying drawings. Like reference numerals may refer to like elements throughout this application.

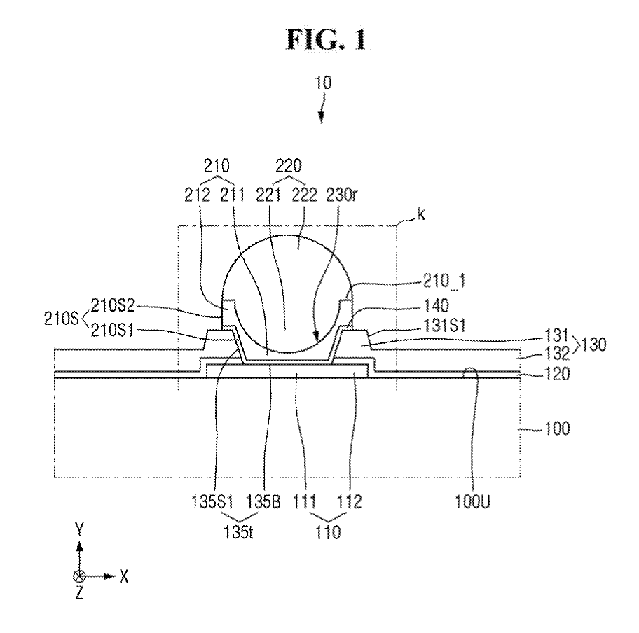

Hereinafter, a semiconductor device according to exemplary embodiments will be described with reference to FIGS. 1 to 7.

FIG. 1 is a cross-sectional view illustrating a semiconductor device according to exemplary embodiments.

Referring to FIG. 1, according to embodiments, a semiconductor device 10 includes a substrate 100, a passivation layer 120, a protection layer 130, a pad 110, a conductive pattern 140, a lower bump 210, and an upper bump 220.

The substrate 100 is, for example, a wafer or a chip unit. According to embodiments, the chip unit is at least one of a plurality of chip units divided from the wafer. When the substrate 100 is the chip unit, the substrate 100 may be, for example, a memory chip or a logic chip. A logic chip is variously designed based on the logical operations implemented thereon. A memory chip includes, for example, a non-volatile memory chip. A non-volatile memory chip includes a flash memory chip, such as a NAND memory flash memory chip or a NOR flash memory chip. In some embodiments, a non-volatile memory chip is one of a phase-change random-access memory (PRAM), a magneto-resistive random-access memory (MRAM), or a resistive random-access memory (RRAM). In some embodiments, the memory chip is a volatile memory chip, such as a dynamic random access memory (DRAM). When the substrate 100 is a wafer, the substrate 100 includes a memory device or a logic device that performs functions as described above.

In some embodiments, an upper surface 100U of the substrate 100 is a surface on which circuit patterns are formed.

According to embodiments, the substrate 100 includes the pad 110. The pad 110 is disposed on, for example, the upper surface 100U of the substrate 100. The pad 110 includes a first part 111 and a second part 112.

According to embodiments, the first part 111 of the pad 110 overlaps in a second direction Y a bottom surface 135B of a trench 135t, where the second direction Y is substantially perpendicular to the upper surface 100U of the substrate 100. The second part 112 of the pad 110 overlaps a first part 131 of the protection layer 130 in the second direction Y. In a cross-sectional view, the second part 112 of the pad 110 is disposed on opposite sides of the first part 111 of the pad 110. In additional, in a plan view, the second part 112 of the pad 110 surrounds the first part 111 of the pad 110.

According to embodiments, a second direction Y is substantially perpendicular to the first direction X that is substantially parallel to the upper surface 100U of the substrate 100.

According to embodiments, the pad 110 is a bonding pad that electrically connects the circuit patterns in the substrate 100 to an external terminal, but embodiments of the inventive concepts are not limited thereto. For example, the pad 110 can be a redistribution layer or a pad connected to a through via (TSV) that penetrates the substrate 100. The pad 110 includes a conductive material such as aluminum.

According to embodiments, the passivation layer 120 and the protection layer 130 are disposed on the substrate 100. The protection layer 130 is disposed on the passivation layer 120.

According to embodiments, the passivation layer 120 and the protection layer 130 cover a portion of the pad 110. In some embodiments, the passivation layer 120 and the protection layer 130 cover the second part 112 of the pad 110. The passivation layer 120 and the protection layer 130 overlap portions of the pad 110 except for those portions of the pad 110 connected to the lower bump 210 and the upper bump 220. In some embodiments, the passivation layer 120 and the protection layer 130 do not overlap the first part 111 of the pad 110.

According to embodiments, the passivation layer 120 includes, for example, a nitride or an oxide. The protection layer 130 includes, for example, a polyimide. However, embodiments of the inventive concepts are not limited thereto. The passivation layer 120 and the protection layer 130 can include, for example, an insulating material that protects the circuit patterns on the upper surface 100U of the substrate 100.

According to embodiments, the protection layer 130 includes the first part 131 and a second part 132. The protection layer 130 includes the trench 135t therein. The trench 135t penetrates through the first part 131 of the protection layer 130 to expose at least a portion of the pad 110.

According to embodiments, the first part 131 of the protection layer 130 includes an inner sidewall that corresponds to a sidewall 135S1 of the trench 135t and protrudes above the second part 132 of the protection layer 130. For example, the first part 131 of the protection layer 130 surrounds the trench 135t, and the second part 132 of the protection layer 130 is spaced apart from the trench 135t by the first part 131. The first part 131 of the protection layer 130 is disposed on the pad 110, and the second part 132 of protection layer 130 is disposed around the pad 110 but not on the pad 110. In some embodiments, the first part 131 of the protection layer 130 is disposed on and around the pad 110.

According to embodiments, the bottom surface 135B of the trench 135t is defined by, for example, an upper surface of the pad 110. The sidewall 135S1 of the trench 135t is defined by, for example, the inner sidewall of the first part 131 of the protection layer 130. The inner sidewall of the first part 131 of the protection layer 130 is opposite to an outer sidewall 131 S1 thereof, that is outside a sidewall of the pad 110.

According to embodiments, the first part 131 and the second part 132 of the protection layer 130 are connected to each other. The outer sidewall 131S1 of the first part 131 of the protection layer 130 is connected to an upper surface of the second part 132 of the protection layer 130. The outer sidewall 131S1 of the first part 131 of the protection layer 130 extends upward in the second direction Y from the upper surface of the second part 132 of the protection layer 130.

According to embodiments, the conductive pattern 140 is conformally disposed along the sidewall 135S1 and the bottom surface 135B of the trench 135t. The conductive pattern 140 extends onto at least a portion of an upper surface of the first part 131 of the protection layer 130. For example, the conductive pattern 140 is disposed between a second part 212 of the lower bump 210 and the first part 131 of the protection layer 130 as well as on the sidewall 135S1 and the bottom surface 135B of trench 135t. The conductive pattern 140 contacts the pad 110.

According to embodiments, the conductive pattern 140 is an under bump metallurgy (UBM) serving as an adhesion, diffusion barrier, or wetting layer.

The conductive pattern 140 includes, for example, chrome (Cr), copper (Cu), nickel (Ni), titanium-tungsten (TiW), or nickel-vanadium (NiV). The conductive pattern 140 includes a stack structure. For example, the conductive pattern 140 can include at least one of Cr/Cr—Cu/Cu, TiW/Cu, Al/NiV/Cu, Ti/Cu, Ni/Au, and Ti/Cu/Ni. The conductive pattern 140 is used as a seed layer in a subsequent plating process.

According to embodiments, the lower bump 210 and the upper bump 220 are disposed on the pad 110 and the conductive pattern 140. The upper bump 220 is disposed on the lower bump 210.

According to embodiments, the lower bump 210 includes a first part 211 that fills at least a portion of the trench 135t and the second part 212 disposed on the first part 131 of the protection layer 130. The first part 211 and the second part 212 of the lower bump 210 are coupled to each other. The first part 211 of the lower bump 210 is disposed adjacent to the first part 131 of the protection layer 130. The second part 212 of the lower bump 210 protrudes over the first part 131 of the protection layer 130. The lower bump 210 has a concave-shaped upper surface.

According to embodiments, an upper surface of the first part 211 of the lower bump 210 is curved downward toward the pad 110.

According to embodiments, a sidewall 210S of the lower bump 210 includes a first sidewall 210S1 of the first part 211 of the lower bump 210 and a second sidewall 210S2 of the second part 212 of the lower bump 210. The sidewall 210S of the lower bump 210 has a stepped shaped or step-like cross-section.

According to embodiments, the first sidewall 210S1 of the lower bump 210 faces the inner sidewall of the first part 131 of the protection layer 130. The first sidewall 210S1 of the lower bump 210 is positioned on the sidewall 135S1 of the trench 135t. The second sidewall 210S2 of the lower bump 210 extends in the second direction Y upward from the first part 131 of the protection layer 130.

According to embodiments, a first surface 210_1 of the lower bump 210 is an upper surface of the second part 212 of the lower bump 210. The first surface 210_1 of the lower bump 210 is spaced apart from and opposite to the bottom surface 135B of the trench 135t. The first surface 210_1 of the lower bump 210 is connected to the sidewall 210S thereof. In particular, the first surface 210_1 of the lower bump 210 contacts the second sidewall 210S2 thereof.

According to embodiments, the first surface 210_1 of the lower bump 210 includes a recess 230r. The recess 230r is a space in the lower bump 210, in which the upper bump 220 is disposed.

According to embodiments, the first part 131 of the protection layer 130 covers at least a portion of the first sidewall 210S 1 of the lower bump 210. The first part 211 of the lower bump 210 is surrounded by the first part 131 of the protection layer 130. The second part 132 of the protection layer 130 surrounds the first part 131 thereof.

According to embodiments, the lower bump 210 includes a metal, such as nickel (Ni), copper (Cu), palladium (Pd), platinum (Pt), gold (Au), or a combination thereof.

According to embodiments, the upper bump 220 includes a first part 221 disposed in the recess 230r and a second part 222 on the first part 221. The first part 221 of the upper bump 220 extends into the lower bump 210

According to embodiments, a portion of the second part 222 of the upper bump 220 is disposed on the second part 212 of the lower bump 210. The upper bump 220 contacts the first surface 210_1 of the lower bump 210 and the upper surface of the first part 211 of the lower bump 210.

According to embodiments, the upper bump 220 includes, for example, a conductive past, such as solder paste or metal paste. The upper bump 220 can include, for example, tin-silver (SnAg) or tin (Sn)

According to embodiments, the lower bump 210 and the upper bump 220 are disposed on the pad 110 and are electrically connected to the pad 110 via the conductive pattern 140.

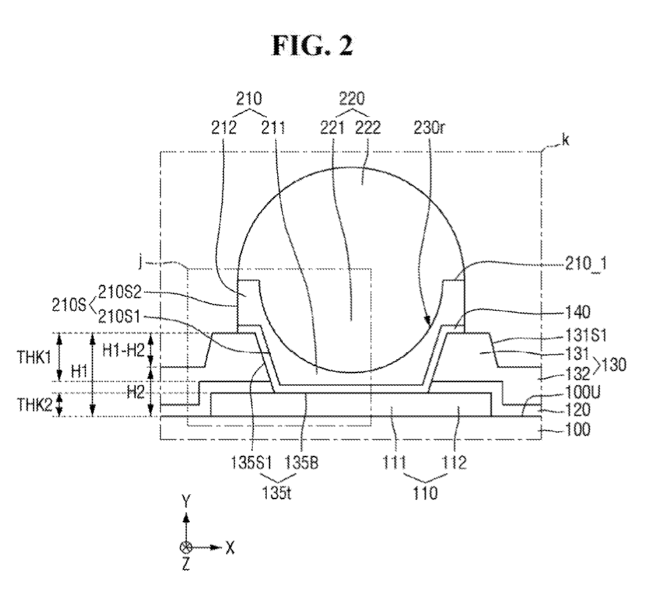

FIG. 2 is an enlarged view of portion k of FIG. 1.

Referring to FIGS. 1 and 2, the second part 112 of the pad 110, the first part 131 of the protection layer 130, and the second part 212 of the lower bump 210 verticallyoverlap each other in the second direction Y.

According to embodiments, a first height H1 from the upper surface 100U of the substrate 100 to the upper surface of the first part 131 of the protection layer 130 is greater than a second height H2 of the upper surface 100U of the substrate 100 to the upper surface of the second part 132 of the protection layer 130. The first part 131 and the second part 132 of the protection layer 130 have a stepped shape due to a difference between the first height H1 and the second height H2.

According to embodiments, a thickness THK1 of the first part 131 of the protection layer 130 is greater than the difference (H1−H2) between the first height H1 and the second height H2. The thickness THK1 of the first part 131 of the protection layer 130 is measured in the second direction Y and is a vertical distance from the lowermost surface of the first part 131 of the protection layer 130 to the uppermost surface thereof.

According to embodiments, the thickness THK1 of the first part 131 of the protection layer 130 is, for example, a distance from the upper surface of the passivation layer 120, which is on the second part 112 of the pad 110, to the upper surface of the first part 131 of the protection layer 130.

According to embodiments, when the thickness THK1 of the first part 131 of the protection layer 130 is greater than the difference (H1−H2) between the first height H1 and the second height H2, the protection layer 130 can provide improved step coverage of the second part 112 of the pad 110.

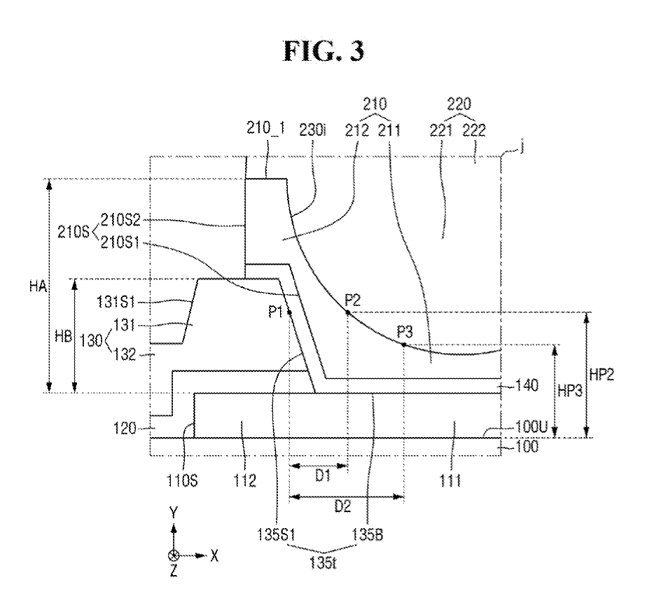

According to embodiments, an interface 230i, shown in FIG. 3, between the lower bump 210 and the upper bump 220 includes the upper surface of the first part 211 of the lower bump 210 and the first surface 210_1 of the lower bump 210. The first surface 210_1 of the lower bump 210 is substantially flat. The upper surface of the first part 211 of the lower bump 210 is concave.

FIG. 3 is an enlarged view of portion j of FIG. 2.

Referring to FIG. 3, according to embodiments, the interface 230i between the lower bump 210 and the upper bump 220 includes second and third points P2 and P3 that are spaced apart from each other.

According to embodiments, the second point P2 is spaced apart from a first point P1 on the sidewall 135S1 of the trench 135t by a first distance D1 in the first direction X. The third point P3 is spaced apart from the first point P1 on the sidewall 135S1 of the trench 135t by a second distance D2 in the first direction X. The first point P1 is an arbitrary point on the sidewall 135S1 of the trench 135t. The second distance D2 is greater than the first distance D1. In some embodiments, a height HP2 from the upper surface 100U of the substrate 100 to the second point P2 is greater than a height HP3 from the upper surface 100U of the substrate 100 to the third point P3.

In some embodiments, a height HB from the bottom surface 135B of the trench 135t to the uppermost surface of the protection layer 130 is from 0.3 to 0.7 times a height HA from the bottom surface 135B of the trench 135t to the upper surface, i.e., the first surface 210_1, of the second part 212 of the lower bump 210. The uppermost surface of the protection layer 130 is the upper surface of the first part 131 of the protection layer 130. The bottom surface 135B of the trench 135t is an interface between the conductive pattern 140 and the pad 110.

According to embodiments, when the height HB from the bottom surface 135B of the trench 135t to the uppermost surface of the protection layer 130 is greater than 0.3 times the height HA from the bottom surface 135B of the trench 135t to the upper surface of the second part 212 of the lower bump 210, a height difference between the height HP2 and the height HP3 occurs such the upper surface of the first part 211 of the lower bump 210 becomes more concave. Therefore, a volume of the lower bump 210 that includes a relatively high stiffness material is less than a volume of the upper bump 220 that includes a relatively low stiffness material. Thus, stress applied to the substrate 100 by the lower bump 210 and the upper bump 220 can be reduced.

According to embodiments, when the height HB from the bottom surface 135B of the trench 135t to the uppermost surface of the protection layer 130 is less than 0.7 times the height HA from the bottom surface 135B of the trench 135t to the upper surface of the second part 212 of the lower bump 210, a volume of the second part 212 of the lower bump 210 can be sufficiently secured to reduce or prevent collapse of the upper bump 220. Since the upper surface of the first part 211 of the lower bump 210 is concave, the volume of the upper bump 220 is greater than that of the lower bump 210. When the volume of the second part 212 of the lower bump 210 is reduced, the upper bump 220 may collapse.

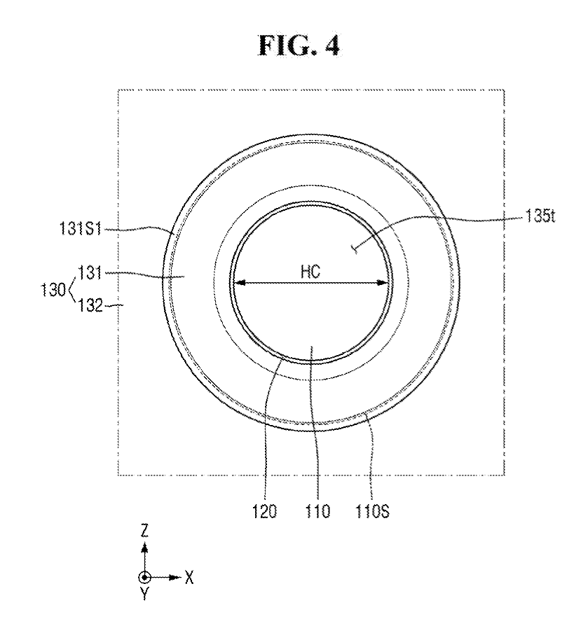

FIGS. 4 to 6 are plan views of a semiconductor device shown in FIG. 2, except for the conductive pattern 140, the lower bump 210, and the upper bump 220, according to exemplary embodiments

Referring to FIGS. 3 and 4, according to embodiments, a planar shape of the pad 110, a planar shape of the trench 135t, and a planar shape of the outer sidewall 131S1 of the first part 131 of the protection layer 130 are substantially similar. A planar shape of the sidewall 110S of the pad 110 is similar to the planar shape of the bottom surface 135B of the trench 135t and a planar shape of the outer sidewall 131S1 of the first part 131 of the protection layer 130. The sidewall 110S of the pad 110 is an interface between the pad 110 and the passivation layer 120 in the first direction X and extends in the second direction Y

In some embodiments, the planar shape of the pad 110, the planar shape of the bottom surface 135B of the trench 135t, are substantially circular, and the planar shape of the first part 131 of the protection layer 130 is substantially annular. However, embodiments of the inventive concepts are not limited thereto. For example, the planar shape of the pad 110 and the planar shape of the bottom surface 135B of the trench 135t can be substantially circular, but the planar shape of the first part 131 of the protection layer 130 can be an octagonal annulus.

According to embodiments, a width HC of the bottom surface 135B of the trench 135t is greater than 0.5 times the height HA shown in FIG. 3. The width HC of the bottom surface 135B of the trench 135t is the greatest width, when measured in the first direction X

According to embodiments, when the width HC of the bottom surface 135B of the trench 135t is greater than 0.5 times the height HA shown in FIG. 3, a volume of the first part 221 of the upper bump 220 is sufficiently secured. If the volume of the first part 221 of the upper bump 220 is not sufficiently secured, the volume of the upper bump 220 is reduced compared to the volume of the lower bump 210. In this case, since the lower bump 210 includes a higher stiffness material than the upper bump 220, stress applied to the substrate 100 by the lower bump 210 and the upper bump 220 can increase. When the volume of the first part 221 of the upper bump 220 is sufficiently secured, stress applied to the substrate 100 is reduced, thus reducing or substantially preventing the generation of cracks in the substrate 100.

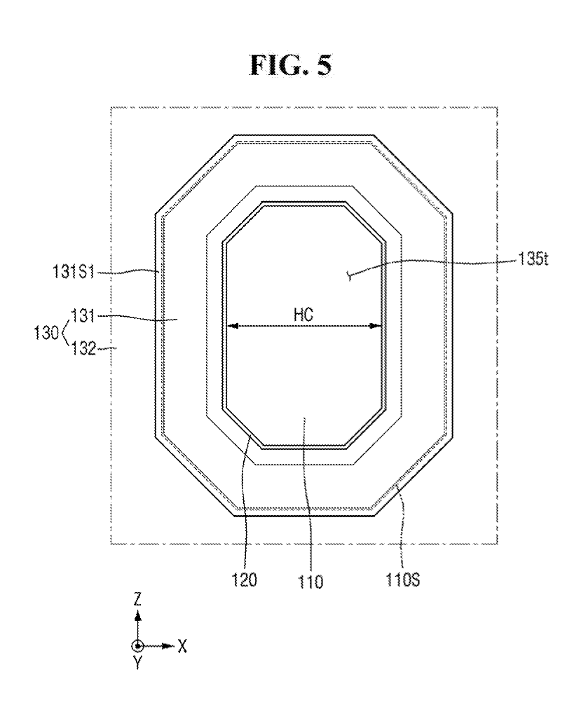

Referring to FIG. 5, according to embodiments, the planar shape of the pad 110, the planar shape of the bottom surface 135B of the trench 135t, are substantially octagonal, and the planar shape of the first part 131 of the protection layer 130 is an octagonal annulus. However, embodiments of the inventive concepts are not limited thereto. For example, the planar shape of the pad 110 and the planar shape of the bottom surface 135B of the trench 135t can be substantially octagonal, but the planar shape of the first part 131 of the protection layer 130 can be a circular annulus.

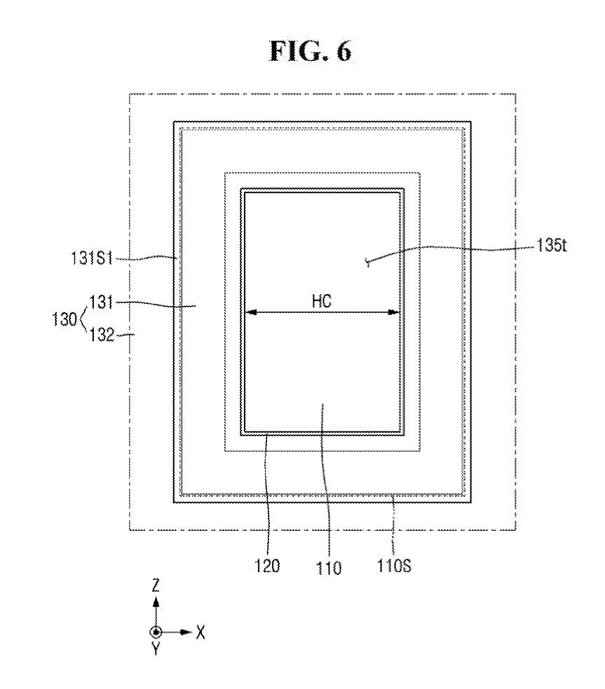

Referring to FIG. 6, according to embodiments, the planar shape of the pad 110, the planar shape of the bottom surface 135B of the trench 135t, are substantially rectangular, and the planar shape of the first part 131 of the protection layer 130 is a rectangular annulus. However, embodiments of the inventive concepts are not limited thereto. For example, the planar shape of the pad 110 and the planar shape of the bottom surface 135B of the trench 135t and the planar shape of the first part 131 of the protection layer 130 may differ from the circular, octagonal, and rectangular shapes and annuli described with reference to FIG. 4 to 6.

Referring again to FIG. 1, according to embodiments, the sidewall 135S1 of the trench 135t and the outer sidewall 131S1 of the first part 131 of the protection layer 130 are inclined with respect to the upper surface 100U of the substrate 100. However, embodiments of the inventive concepts are not limited thereto.

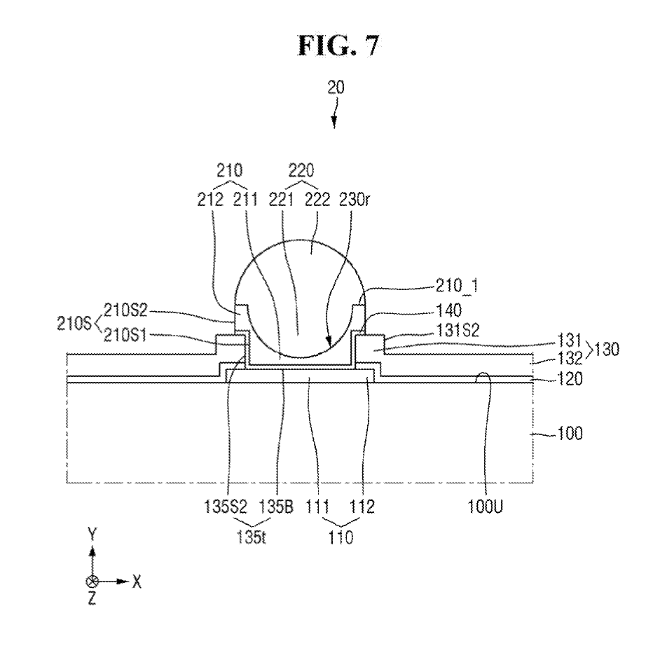

FIG. 7 is a cross-sectional view of a semiconductor device 20 according to exemplary embodiments.

Referring to FIG. 7, a sidewall 135S2 of the trench 135t and an outer sidewall 131S2 of the first part 131 of the protection layer 130 are substantially perpendicular to the upper surface 100U of the substrate 100.

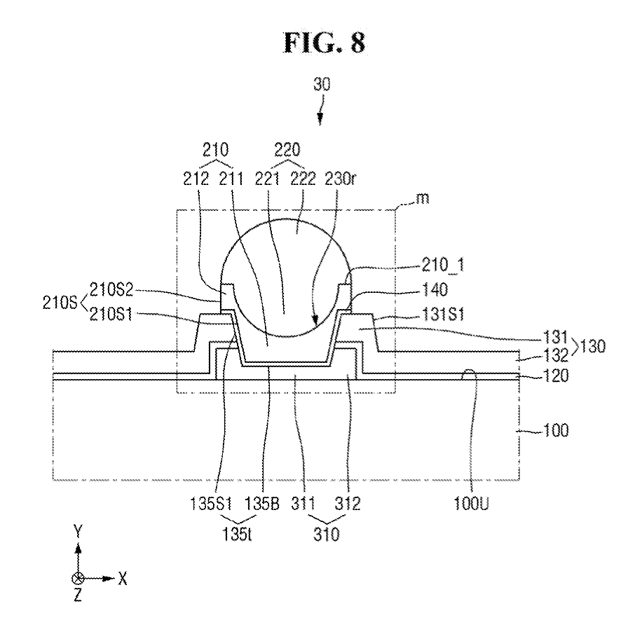

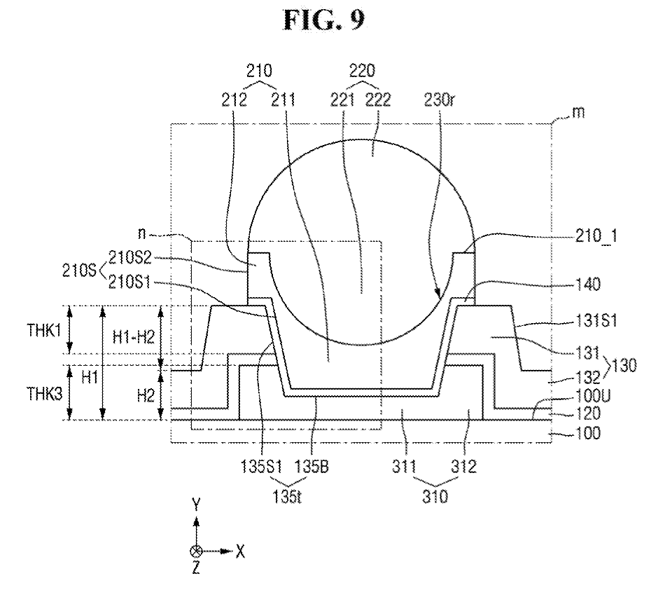

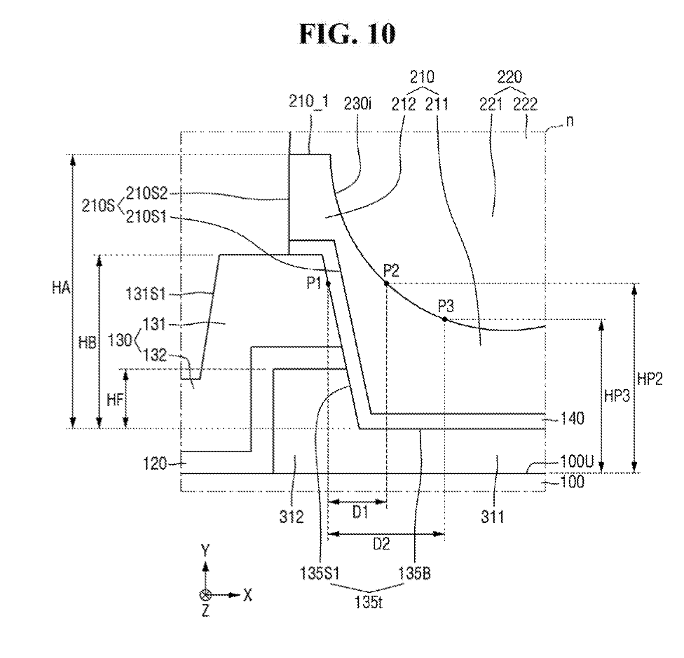

Hereinafter, a semiconductor device according to exemplary embodiments will be described with reference FIGS. 8 to 10. FIG. 8 is a cross-sectional view of a semiconductor device 30 according to exemplary embodiments. FIG. 9 is an enlarged view of portion m of FIG. 9. FIG. 10 is an enlarged view of portion n of FIG. 9. Descriptions of those components already described with respect to FIGS. 1-7 will be omitted.

Referring to FIGS. 8 and 9, according to embodiments, a thickness THK3 of a pad 310 is greater than the thickness THK2 of the pad 110 shown in FIG. 2.

According to embodiments, the pad 310 includes a first part 311 and a second part 312 on opposite sides of the first part 311. The first part 311 of the pad 310 corresponds to the first part 111 of the pad 110 of FIG. 1. The second part 312 of the pad 310 corresponds to the second part 112 of the pad 110 of FIG. 1

According to embodiments, the trench 135t extends into the pad 310. For example, a portion of the conductive pattern 140 and a portion of the first part 211 of the lower bump 210 protrude into the pad 310. The other potion of the first part 211 of the lower bump 210 extends over the second part 312 of the pad 310.

According to embodiments, a thickness of the first part 311 of the pad 310 is less than a thickness of the second part 312 of the pad 310. The thickness is measured in the second direction Y with respect to the upper surface 100U of the substrate 100.

Referring to FIG. 10, according to embodiments, a height HF from the bottom surface 135B of the trench 135t to an upper surface of the second part 312 of the pad 310 is less than 0.5 times the height HB from the bottom surface 135B of the trench 135t to the uppermost surface of the protection layer 130.

In this case, according to embodiments, the thickness of the first part 131 of the protection layer 130 is sufficiently secured, thus providing improved step coverage of the protection layer 130 on the second part 312 of the pad 310.

According to embodiments, the sidewall 135S1 of the trench 135t and the outer sidewall 131 S1 of the first part 131 of the protection layer 130 are inclined with respect to the upper surface 100U of the substrate 100. However, embodiments of the inventive concepts are not limited thereto.

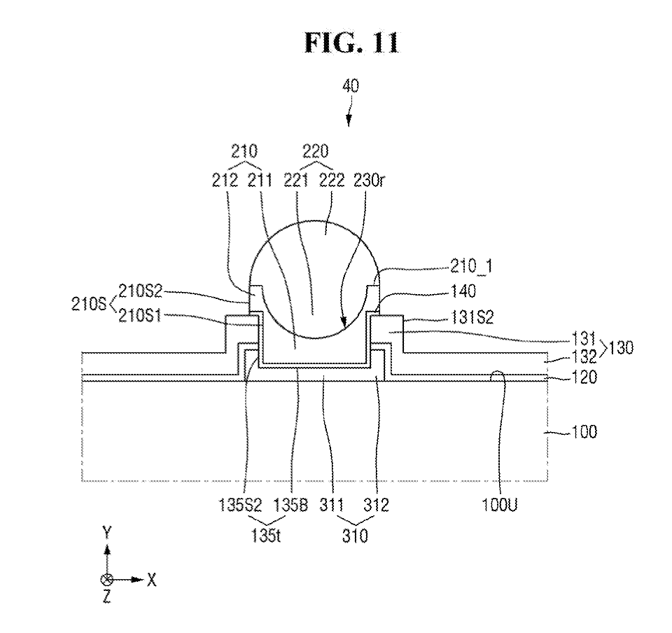

FIG. 11 is a cross-sectional view illustrating a semiconductor device 40 according to exemplary embodiments.

Referring to FIG. 11, according to embodiments, the sidewall 135S2 of the trench 135t and the outer sidewall 131S2 of the first part 131 of the protection layer 130 are substantially perpendicular to the upper surface 100U of the substrate 100.

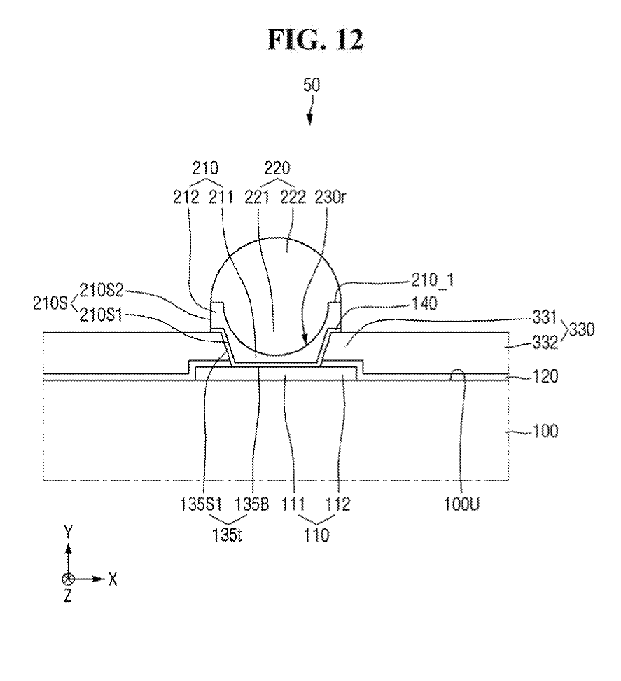

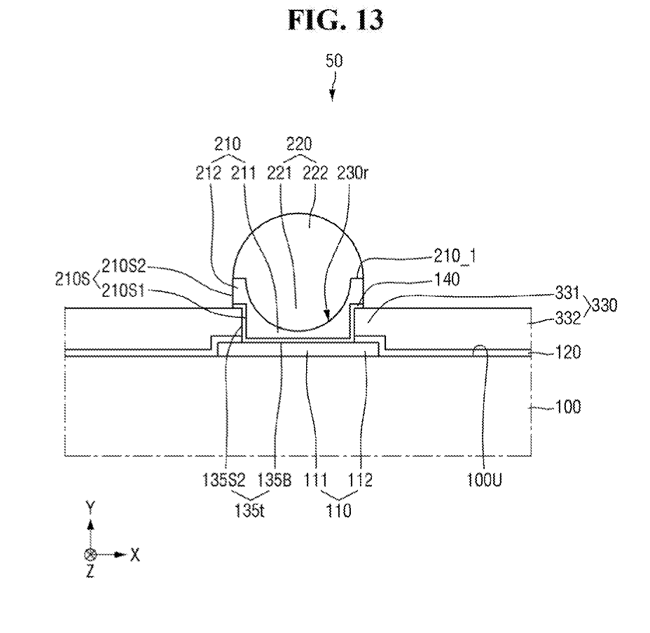

Hereinafter, a semiconductor device according to exemplary embodiments will be described with reference FIGS. 12 and 13.

FIG. 12 is a cross-sectional view of a semiconductor device 50 according to exemplary embodiments.

Referring to FIG. 12, according to embodiments, a protection layer 330 does not have a step. An upper surface of a first part 331 of the protection layer 330 is substantially coplanar with an upper surface of a second part 332 of the protection layer 330. The first part 331 of the protection layer 330 vertically overlaps the second part 112 of the pad 110 and the second part 212 of the lower bump 210.

According to embodiments, a thickness of the second part 332 of the protection layer 330 is greater than a thickness of the second part 132 of the protection layer 130 of FIG. 1. A thickness of the first part 331 of the protection layer 330 is substantially equal to the thickness of the first part 131 of the protection layer 130 of FIG. 1.

According to embodiments, the sidewall 135S1 of the trench 135t is inclined with respect to the upper surface 100U of the substrate 100. However, embodiments of the inventive concepts are not limited thereto.

FIG. 13 is a cross-sectional view of a semiconductor device 60 according to exemplary embodiments.

Referring to FIG. 13, according to embodiments, the sidewall 135S2 of the trench 135t is substantially perpendicular to the upper surface 100U of the substrate 100.

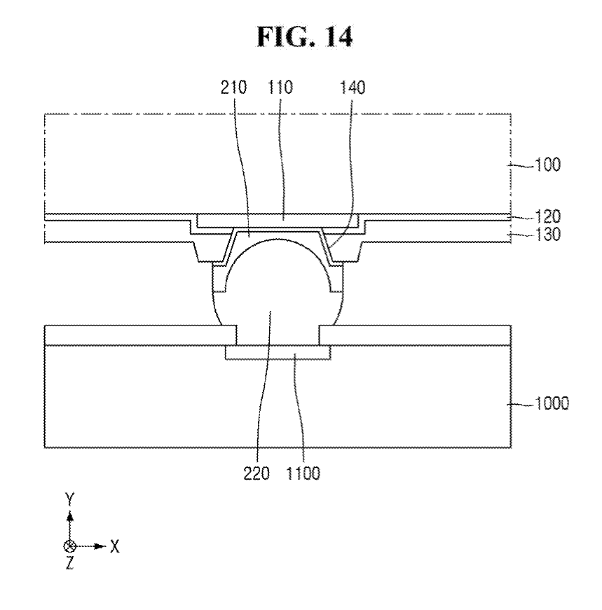

FIG. 14 illustrates a semiconductor package that includes a semiconductor device according to exemplary embodiments.

Referring to 14, according to embodiments, the semiconductor device 10 of FIG. 1 is mounted on a package substrate 1000 in a flip chip manner. The upper bump 220 and the lower bump 210 electrically connect the pad 110 to a conductive line 1100 of the package substrate 1000. In some embodiments, at least one of the semiconductor devices 20, 30, 40, 50, and 60 shown in FIGS. 7, 8, 11, 12, and 13 can be mounted on the package substrate 1000, instead of or in addition to the semiconductor device 10 of FIG. 1.

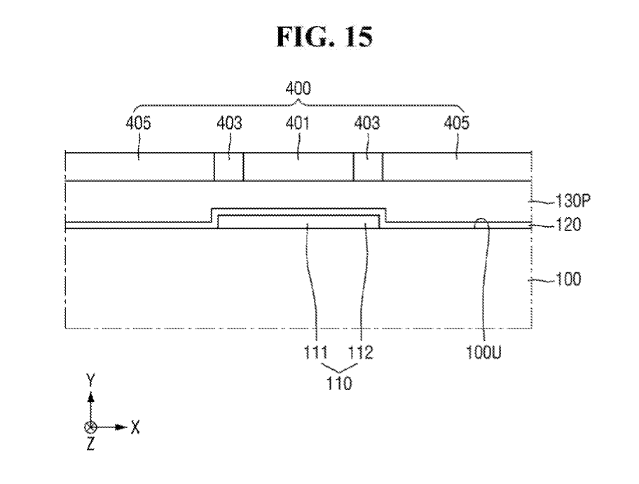

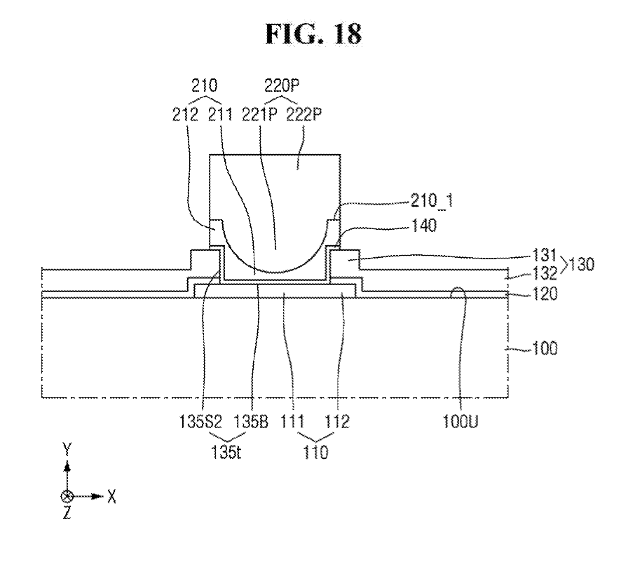

FIGS. 15 and 18 illustrate a method of manufacturing the semiconductor device 20 of FIG. 7 according to exemplary embodiments.

Referring to FIG. 15, according to embodiments, the substrate 100 having the upper surface 100U, on which the pad 110, the passivation layer 120, and a pre-protection layer 130p are formed, is provided.

According to embodiments, a photosensitive layer 400 is formed on the pre-protection layer 130p. The photosensitive layer 400 includes a first region 401, a second region 403, and a third region 405. The second region 403 and the third region 405 are disposed on opposite sides, respectively, of the first region 401.

According to embodiments, the first region 401 of the photosensitive layer 400 corresponds to the first part 111 of the pad 110. The second region 403 of the photosensitive layer 400 corresponds to a portion of the pre-protection layer 130p to be formed as the first part 131 of the protection layer 130 of FIG. 1 in the following process. The third region 405 of the photosensitive layer 400 corresponds to another portion of the pre-protection layer 130p to be formed as the second part 132 of the protection layer 130 of FIG. 1 in the following process.

The photosensitive layer 400 is formed of a positive photoresist or a negative photoresist. Various types of photoresists may be used based on the frequency range of the light sources used in a photolithography process and the shapes of the patterns to be formed. The light source includes, for example, ArF (193 nm), KrF (248 nm), EUV (Extreme Ultra Violet), VUV (Vacuum Ultra Violet, 157 nm), E-beam, X-ray, or ion beam, but embodiments are not limited thereto.

In some embodiments, the photosensitive layer 400 is formed of a positive photoresist. In a photolithography process, the amount of light that penetrates the first region 401 of the photosensitive layer 400 is greater than the amount of light that penetrates the second and third regions 403 and 405 thereof. The amount of light that penetrates the third region 405 of the photosensitive layer 400 is greater than the amount of light that penetrates the second region 403 thereof.

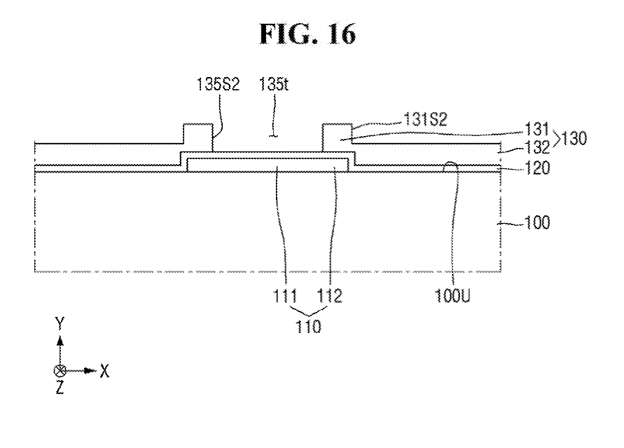

Referring to FIG. 16, according to embodiments, a portion of the pre-protection layer 130p under the first region 401 of the photosensitive layer 400 is removed to expose the passivation layer 120. Thus, the trench 135t can be formed.

According to embodiments, another portion of the pre-protection layer 130p under the third region 405 of the photosensitive layer 400 is partially removed such that the outer sidewall 131S2 of the protection layer 130 is formed. The other portion of the pre-protection layer 130p under the second region 403 of the photosensitive layer 400 remains substantially unetched. Therefore, the first part 131 and the second part 132 of the protection layer 130 are formed.

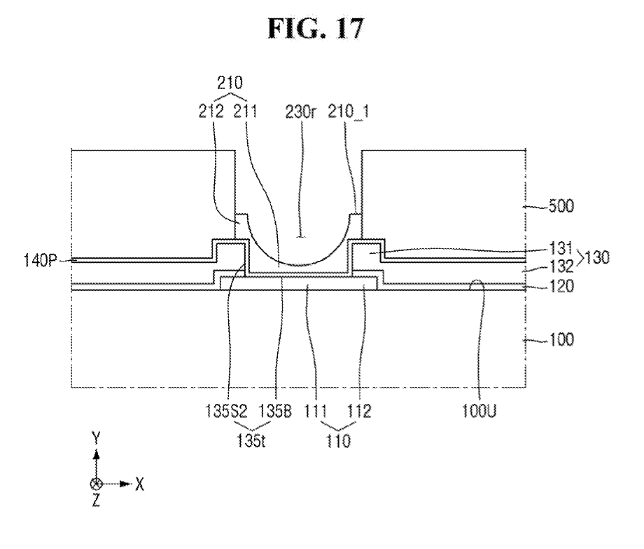

Referring to FIG. 17, according to embodiments, a portion of the passivation layer 120 exposed by the trench 135t is removed.

According to embodiments, a conductive layer 140p is formed on the protection layer 130, the sidewall 135S2 of the trench 135t, and the bottom surface 135B of the trench 135t. A mask pattern 500, that completely covers the second part 132 of the protection layer 130 and that partially covers the first part 131 of the protection layer 130, is formed.

According to embodiments, a plating process is performed on a region exposed by the mask pattern 500 to form the lower bump 210. The lower bump 210 that fills at least a portion of the trench 135t is formed. Further, the lower bump 210 is formed along a portion of a sidewall of the mask pattern 500 and a surface of the first part 131 of the protection layer 130. The lower bump 210 is formed to have the concave upper surface, and thus, the recess 230r of a concave shape is formed.

Referring to FIG. 18, according to embodiments, a pre-upper bump 220p is formed on the lower bump 210. The pre-upper bump 220p includes a pre-first part 221p and a pre-second part 222p. The pre-first part 221p fills the recess 230r. The pre-second part 222p is formed on the pre-first part 221p and the second part 212 of the lower bump 210.

According to embodiments, after forming the pre-upper bump 220p, the mask pattern 500 of FIG. 17 is removed.

Thereafter, according to embodiments, a reflow process is performed on the pre-upper bump 220p such that a surface of the pre-upper bump 220p is curved. Thus, the upper bump 220 of FIG. 7 is formed.

While embodiments of the present inventive concepts have been shown and described with reference to exemplary embodiments thereof, it will be understood by those of ordinary skill in the art that various changes in form and details may be made thereto without departing from the spirit and scope of the embodiments of the present inventive concepts as set forth by the following claims.

1. A semiconductor device, comprising:
a substrate;
a protection layer on the substrate, the protection layer including a trench that penetrates therethrough;
a lower bump that includes a first part that fills at least a portion of the trench and a second part on the protection layer, wherein an upper surface of the first art of the lower bump is curved downward toward the substrate; and
an upper bump on the lower bump,
wherein the protection layer includes a first part that surrounds the trench and a second part that surrounds the first part, and
a first height from an upper surface of the substrate to an upper surface of the first part of the protection layer is greater than a second height from the upper surface of the substrate to an upper surface of the second part of the protection layer.

2. The semiconductor device according to claim 1, wherein the lower bump includes a recess, and
the upper bump includes a first part in the recess and a second part on the first part.

3. The semiconductor device according to claim 1, wherein an upper surface of the first part of the lower bump includes a second point spaced apart by a first distance from a first point on a sidewall of the trench in a first direction parallel to the upper surface of the substrate and a third point spaced apart by a second distance from the first point in the first direction,
the second distance is greater than the first distance, and
a height from the upper surface of the substrate to the second point is greater than a height from the upper surface of the substrate to the third point.

4. The semiconductor device according to claim 1, wherein a height from a bottom surface of the trench to the upper surface of the first part of the protection layer is from 0.3 to 0.7 times a height from the bottom surface of the trench to the upper surface of the second part of the lower bump.

5. The semiconductor device according to claim 1, wherein a thickness of the first part of the protection layer is greater than a difference between the first height and the second height.

6. The semiconductor device according to claim 1, wherein the substrate includes a pad,
the lower bump is disposed on the pad, and
the second part of the lower bump horizontally overlaps a portion of the pad and the first part of the protection layer.

7. The semiconductor device according to claim 1, wherein the substrate includes a pad, and
the trench further protrudes into the pad.

8. A semiconductor device, comprising:
a substrate that includes a pad;
a protection layer on the substrate, the protection layer including a trench that exposes the pad;
a lower bump that includes a first part that fills at least a portion of the trench and a second part on the protection layer, wherein an upper surface of the first part is curved downward toward the pad; and
an upper bump on the lower bump,
wherein a height from a bottom surface of the trench to an uppermost surface of the protection layer is from 0.3 to 0.7 times a height from the bottom surface of the trench to an upper surface of the second part of the lower bump.

9. The semiconductor device according to claim 8, wherein the protection layer includes a first part that surrounds the trench and a second part that surrounds the first part, and
a first height from an upper surface of the substrate to an upper surface of the first part of the protection layer is greater than a second height from the upper surface of the substrate to an upper surface of the second part of the protection layer.

10. The semiconductor device according to claim 9, wherein the uppermost surface of the protection layer is the upper surface of the first part of the protection layer.

11. The semiconductor device according to claim 9, wherein the second part of the lower bump horizontally overlaps a portion of the pad and the first part of the protection layer.

12. The semiconductor device according to claim 9, wherein a thickness of the first part of the protection layer is greater than a difference between the first height and the second height.

13. The semiconductor device according to claim 8, wherein the lower bump includes a recess, and
the upper bump includes a first part in the recess and a second part on the first part.

14. The semiconductor device according to claim 8, wherein an upper surface of the first part of the lower bump includes a second point spaced apart by a first distance from a first point on a sidewall of the trench in a first direction parallel to an upper surface of the substrate and a third point spaced apart by a second distance from the first point in the first direction,
the second distance is greater than the first distance, and
a height from the upper surface of the substrate to the second point is greater than a height from the upper surface of the substrate to the third point.

15. The semiconductor device according to claim 8, wherein the trench further protrudes into the pad.

16. A semiconductor device, comprising:
a substrate that includes a pad;
a conductive pattern on the pad;
a lower bump on the conductive pattern, wherein a portion of an upper surface of the lower bump is curved downward toward the pad;
a protection layer on the substrate, the protection layer including a first part that covers at least a portion of a sidewall of the lower bump and a second part that surrounds the first part; and
an upper bump on the lower bump, the upper bump including a first part that protrudes into the lower bump and a second part on the first part;
wherein the first part of the protection layer protrudes above the second part of the protection layer.

17. The semiconductor device according to claim 16, wherein the lower bump includes a recess, and
the first part of the upper bump protrudes into the recess.

18. The semiconductor device according to claim 16, wherein a height from an interface between the conductive pattern and the pad to an upper surface of the first part of the protection layer is from 0.3 to 0.7 times a height from the interface between the conductive pattern and the pad to an upper surface of the second part of the lower bump.

19. The semiconductor device according to claim 16, wherein the lower bump includes a first part surrounded by the first part of the protection layer and a second part on the first part of the protection layer.

20. The semiconductor device according to claim 16, wherein a first height from an upper surface of the substrate to an upper surface of the first part of the protection layer is greater than a second height from the upper surface of the substrate to an upper surface of the second part of the protection layer, and
a thickness of the first part of the protection layer is greater than a difference between the first height and the second height.
